(19) United States
(12) Patent Application Publication
(10) Pub. No.: US 2015/0366103 A1
(43) Pub. Date: Dec. 17, 2015

(54) Signal Transmission Device and Cooling Device

(71) Applicant: Hitachi Metals, Ltd., Tokyo (JP)

(72) Inventor: Akihito KANTANI, Tsuchiura (JP)

(21) Appl. No.: 14/739,280

(22) Filed: Jun. 15, 2015

(30) Foreign Application Priority Data
Jun. 16, 2014 (JP) 2014-123699

(51) Int. Cl. H05K 7/20

(52) U.S. Cl. CPC H05K 7/2039

(57) ABSTRACT

The heat generating elements are more effectively cooled by improving a heat radiating property of the heat generating elements provided so as to be adjacent to each other. An extending direction of fins of a second heat sink corresponding to a second communication-use LSI is made to intersect with an extending direction of fines of a third heat sink corresponding to a third communication-use LSI. Thus, a cooling air that has passed through the second heat sink is prevented from passing through the third heat sink. Therefore, a cooling air that is not warmed can be supplied to both of the second heat sink and the third heat sink. Thus, each heat radiating property of the second and third communication-use LSIs provided so as to be adjacent to each other can be improved. As a result, both of the second and third communication-use LSIs can be efficiently cooled.

### CROSS-REFERENCE TO RELATED APPLICATION

The present application claims priority from Japanese Patent Application No. 2014-123699 filed on Jun. 16, 2014, the content of which is hereby incorporated by reference into this application.

### TECHNICAL FIELD OF THE INVENTION

The present invention relates to a signal transmission device provided with a heat generating element mounted on a substrate and a heat sink for cooling the heat generating element, and also relates to a cooling device provided with a signal transmission device, a casing that houses the signal transmission device and a cooling mechanism that introduces outside air into the casing and exhausts heat of the signal transmission device outside the casing.

### BACKGROUND OF THE INVENTION

Conventionally, as one of communication methods for allowing a plurality of computers connected by the LAN (Local Area Network) to efficiently communicate with each other, an Ethernet system (Ethernet (registered trademark)) is proposed. Moreover, in order to configure a complicated Ethernet system, a communication provider (carrier) has a plurality of Ethernet switches (switching hubs). Each of these Ethernet switches is provided with a plurality of line cards (extension cards) composed of substrates on which a plurality of communication-use LSIs (Large Scale Integration) are mounted, and these line cards are housed in the casing forming the Ethernet switch in a state in which these line cards are adjacent to each other.

Moreover, a temperature of the plurality of the communication-use LSIs becomes extremely high during an operation for processing high-speed signals, and this causes a malfunction of the communication-use LSI. Therefore, it is necessary to efficiently cool the plurality of the communication-use LSIs and consequently to preliminarily prevent the malfunction of the communication-use LSI. For example, Japanese Patent Application Laid-Open Publication No. 2003-188321 (Patent Document 1 (FIG. 1)) describes a technique for improving the heat radiating property of the heat generating element such as the communication-use LSI.

In the Patent Document 1, a pair of heat generating elements are provided so as to extend along a flowing direction of cooling air, and these heat generating elements have upwind side fins and downwind side fins attached thereon through a common base plate. The extending direction of the upwind side fins and the extending direction of the downwind side fins correspond to the flowing direction of the cooling air. Therefore, the cooling air that has passed through the upwind side fins is set so as to pass through the downwind side fins.

Thus, in order to effectively cool the heat generating element corresponding to the upwind side fins and the heat generating element corresponding to the downwind side fins, the arrangement density of the upwind side fins is made smaller than the arrangement density of the downwind side fins. This arrangement eliminates such a state that the heat generating elements corresponding to the downwind side fins are not effectively cooled.

### SUMMARY OF THE INVENTION

However, the technique described in the above-described Patent Document 1 has a configuration in which a cooling air that has passed through the upwind side fins and has been warmed is set so as to pass through the downwind side fins. Therefore, the cooling air passing through the downwind side fins is warm, and therefore, the cooling efficiency of the heat generating elements corresponding to the downwind side fins is never good. Consequently, a device for improving the cooling efficiency of the heat generating elements corresponding to the downwind side fins has been required.

An object of the present invention is to provide a signal transmission device and a cooling device capable of improving the heat radiating properties of the heat generating elements provided so as to be adjacent to each other, and consequently capable of effectively cooling the heat generating elements.

In one aspect of the present invention, a signal transmission device is provided with heat generating elements mounted on a substrate and heat sinks for cooling the heat generating element, one heat sink corresponding to one heat generating element of the heat generating elements provided on the substrate so as to be adjacent to each other has a fin extending direction that intersects with a fin extending direction of fins of the other heat sink corresponding to the other heat generating element thereof.

In another aspect of the present invention, a flowing direction of a cooling air on the upstream side of a cooling air flow passage formed on the substrate is the fin extending direction of one of the heat sinks, and a flowing direction of the cooling air on the downstream side of the cooling air flow passage is the fin extending direction of the other heat sink.

In still another aspect of the present invention, one heat sink is provided on the upstream side of the cooling air flow passage formed on the substrate, the other heat sink is provided on the downstream side of the cooling air flow passage, and an interval between the fins of the one heat sink is narrower than an interval between the fins of the other heat sink.

In still another aspect of the present invention, a cooling-air introduction member for introducing a cooling air to the heat sink is provided on the substrate.

In still another aspect of the present invention, the one heat sink and the other heat sink are provided so as to be next to each other along the extending direction of the cooling air flow passage formed on the substrate and are arranged in a direction intersecting with the cooling air flow passage.

In still another aspect of the present invention, a cooling device is provided with a signal transmission device, a casing that houses the signal transmission device and a cooling mechanism that introduces outside air into the casing and exhausts heat of the signal transmission device out of the casing. The signal transmission device has heat generating elements mounted on a substrate and heat sinks for cooling the heat generating elements, one heat sink corresponding to one heat generating element of the heat generating elements provided on the substrate so as to be adjacent to each other has a fin extending direction that intersects with a fin extending direction of fins of the other heat sink corresponding to the other heat generating element, and the cooling mechanism is provided with an air-suction inlet and an exhaust outlet provided on the casing and with a fan that is provided on at least either one of the air-suction inlet and the exhaust outlet so as to form a cooling air flow passage on the substrate.

In still another aspect of the present invention, a flowing direction of a cooling air on the upstream side of the cooling air flow passage is the fin extending direction of one heat sink, and a flowing direction of the cooling air on the downstream side of the cooling air flow passage is the fin extending direction of the other heat sink.

In still another aspect of the present invention, one heat sink is provided on the upstream side of the cooling air flow passage, the other heat sink is provided on the downstream side of the cooling air flow passage, and an interval between the fins of the one heat sink is narrower than an interval between the fins of the other heat sink.

In still another aspect of the present invention, a cooling-air introduction member for introducing a cooling air to the heat sink is provided on the substrate.

In still another aspect of the present invention, the one heat sink and the other heat sink are provided so as to be next to each other along the extending direction of the cooling air flow passage and are also arranged in a direction intersecting with the cooling air flow passage.

According to the present invention, since the extending direction of fins of one heat sink corresponding to one heat generating element intersects with the extending direction of fins of the other heat sink corresponding to the other heat generating element, a cooling air that has passed through one heat sink is prevented from passing through the other heat sink. Thus, cooling air flow that has not been warmed can be supplied to both of the one heat sink and the other heat sink. Therefore, each heat radiating property of the one heat generating element and the other heat generating element provided so as to be adjacent to each other is improved, and besides, both of the heat generating elements can be efficiently cooled.

### BRIEF DESCRIPTIONS OF THE DRAWINGS

FIG. 1 is a front view showing an Ethernet switch of the present invention;

FIG. 2 is a back view showing the Ethernet switch of the present invention;

FIG. 3 is a view on an arrow A of FIG. 1 for explaining a flow of a cooling air inside a casing;

FIG. 4 is a plan view showing line cards housed inside the casing in detail;

FIG. 5A is a view showing a first heat sink used for cooling a first communication-use LSI in detail;

FIG. 5B is a view showing the first heat sink used for cooling the first communication-use LSI in detail;

FIG. 5C is a view showing the first heat sink used for cooling the first communication-use LSI in detail;

FIG. 6 is a cross-sectional view taken along a line B-B of FIG. 4;

FIG. 7A is a view showing a second heat sink used for cooling a second communication-use LSI in detail;

FIG. 7B is a view showing the second heat sink used for cooling the second communication-use LSI in detail;

FIG. 8A is a view showing a third heat sink used for cooling a third communication-use LSI in detail;

FIG. 8B is a view showing the third heat sink used for cooling the third communication-use LSI in detail; and

FIG. 9 is a view explaining flows of cooling air with respect to a substrate.

### DESCRIPTIONS OF THE PREFERRED EMBODIMENTS

Hereinafter, one embodiment of the present invention will be explained in detail by using the drawings.

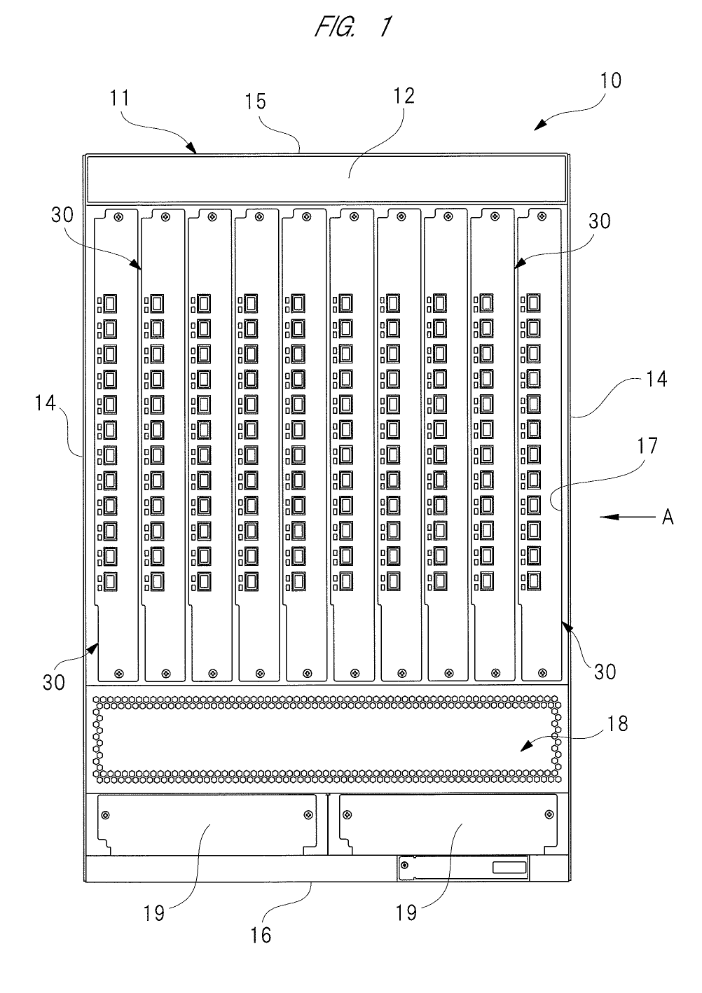

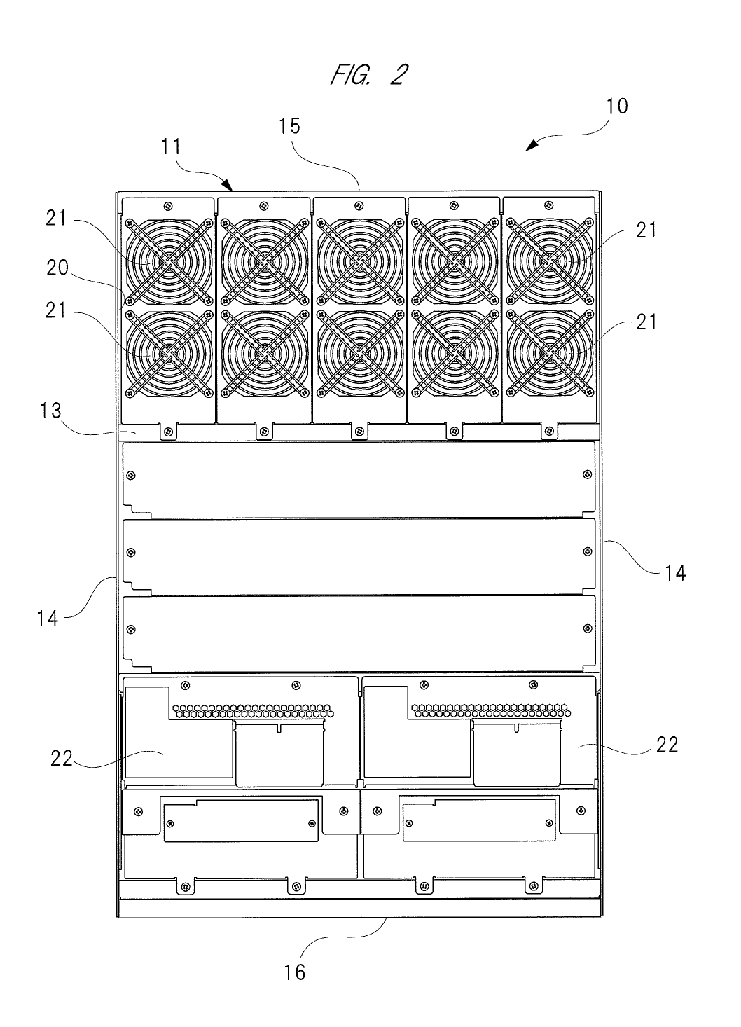

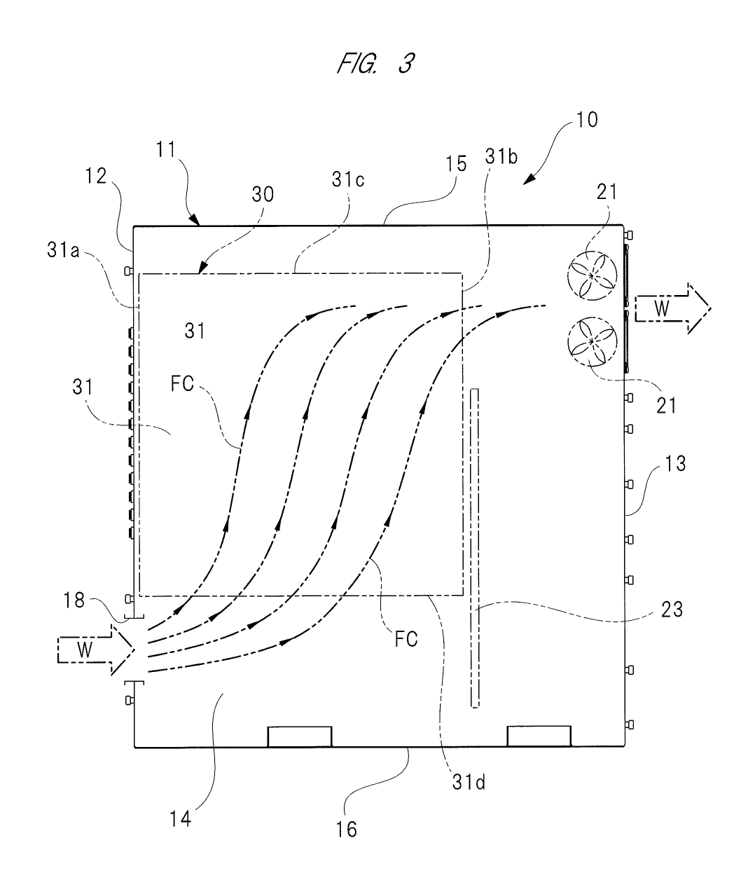

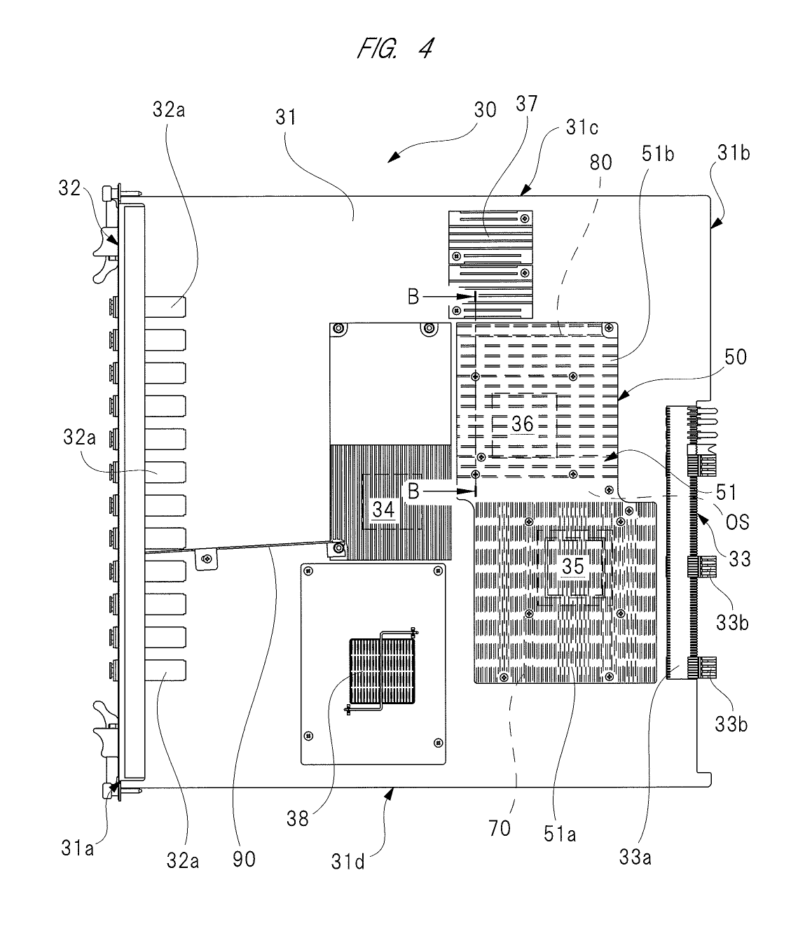

FIG. 1 is a front view showing an Ethernet switch of the present invention, FIG. 2 is a back view showing the Ethernet switch of the present invention, FIG. 3 is a view with an arrow A of FIG. 1 for explaining a flow of a cooling air inside a casing, and FIG. 4 is a plan view showing line cards housed inside the casing in detail.

As shown in FIGS. 1 to 3, an Ethernet switch 10 houses total of ten line cards 30, and controls these line cards 30 so as to be in cooperation with each other. The Ethernet switch 10 is provided with a casing 11 formed into a substantially rectangular parallelepiped shape, and the casing 11 is provided with a front wall 12, a back wall 13, a pair of side walls 14, a top wall 15 and a bottom wall 16.

As shown in FIG. 1, an insertion opening section 17 for use in housing the line cards 30 into the casing 11 is formed on the front wall 12. The insertion opening section 17 occupies most of the front wall 12, and the insertion opening section 17 is closed by inserting all of total of ten line cards 30 into the insertion opening section 17. Note that guide rails (not shown) that guide the insertion of the line cards 30 into the insertion opening section 17 are provided inside the casing 11 in the insertion opening section 17, and these guide rails are provided on both of the top wall 15 side and the bottom wall 16 side. Thus, as shown in FIG. 1, the line cards 30 are smoothly inserted from the insertion opening section 17 into the casing 11 without being stacked in a state in which the line cards 30 are vertically stood.

The insertion opening section 17 is formed on a portion of the front wall 12 which is close to the top wall 15, and an air suction inlet 18 is provided on a portion of the insertion opening section 17 which is close to the bottom wall 16. The air suction inlet 18 is formed of an aggregate body of numerous small hexagonal pores, and formed into a substantially network shape. Moreover, the air suction inlet 18 communicates with the inside and outside of the casing 11 so as to introduce a cooling air W (see FIG. 3) into the casing 11. In FIG. 1, note that some of the pores forming the air suction inlet 18 are omitted for easy view.

On a portion of the front wall 12 which is closer to the bottom wall 16 from the air suction inlet 18, a pair of managing cards 19 (not shown) are provided. These managing cards 19 are the same cards as each other, and are functional members for use in controlling and managing the plurality of line cards 30 housed in the casing 11, a large-size fan 21, a power supply 22 and others. Here, by providing the same managing cards 19 as each other, even if one of them is broken, the other is functioned. Thus, the possibility of occurrence of failure such as communication stop is significantly reduced. That is, the same managing cards 19 are used in order to provide a fail-safe function to the Ethernet switch 10.

As shown in FIG. 2, on a portion of the back wall 13 which is close to the top wall 15, an exhaust outlet 20 for exhausting the cooling air W introduced into the casing 11 to the outside of the casing 11 is provided. On the exhaust outlet 20, total of ten large-size fans 21 for use in cooling the line cards 30 by flowing the cooling air W are provided. These large-size fans 21 are arranged in two rows each including five fans so as to cover the exhaust outlet 20, and they are rotationally driven so as to suck the cooling air W from the air suction inlet 18 and exhaust the cooling air W from the exhaust outlet 20. Here, the large-size fans 21 provided in the exhaust outlet 20 form fans in the present invention.

In this manner, by arranging the air suction inlet 18 on a portion of the front wall 12 which is close to the bottom wall 16 (see FIG. 1), arranging the exhaust outlet 20 on a portion of the back wall 13 which is close to the top wall 15 (see FIG. 2), and providing the large-size fans 21 to the exhaust outlet 20, a cooling air flow passage FC through which the cooling air W flows so as to draw a substantially S letter is formed as shown in FIG. 3. More specifically, the cooling air flow passage FC is formed on the substrate 31 forming the line card 30, and the cooling air flow passage FC is extended substantially vertically from the bottom wall 16 toward the top wall 15 in a portion of the substrate 31 from the air suction inlet 18 side to the substantially center portion while the cooling air flow passage FC is bent toward the exhaust outlet 20 in a portion to the exhaust outlet 20 side of the substrate 31 beyond the substantially center portion of the substrate 31.

Here, the air suction inlet 18, the exhaust outlet 20 and the large-size fans 21 configure the cooling mechanism in the present invention. Moreover, the line cards 30, the casing 11 that houses the line cards 30, the air suction inlet 18 that introduces outside air into the casing 11 and exhausts heat of the line cards 30 outside of the casing 11, the Ethernet switch 10 that is provided with the exhaust outlet 20 and the large-size fans 21 configure the cooling device in the present invention.

On a portion of the back wall 13 which is close to the bottom wall 16, a pair of power supplies 22 (not shown in detail) are provided. These power supplies 22 are the same devices as each other, and the same power supplies 22 are used in order to provide a fail-safe function as similar to the pair of managing cards 19. The power supplies 22 are designed to supply a driving current to the large-size fans 21, the pair of managing cards 19 and others in addition to a main board 23 (see FIG. 3) formed on a portion which is inside the casing 11 and close to the back wall 13. Note that a connector 33 (see FIG. 4) of the line card 30 is connected to a slot (not shown) of the main board 23. Thus, the driving current is supplied from the main board 23 to the line card 30.

As shown in FIG. 4, the line card 30 serving as a signal transmission device is provided with the substrate 31 having a substantially square shape whose front surface and rear surface have printed wirings (not shown) formed thereon. The substrate 31 is formed by, for example, stacking cloths made of glass fibers and impregnating the closes in an epoxy resin. In a state in which the line cards 30 are housed in the casing 11, a front surface side portion 31a positioned on the front wall 12 side of the casing 11, a back surface side portion 31b positioned on the back wall 13 side of the casing 11, a top wall side portion 31c positioned on the top wall 15 side of the casing 11 and a bottom wall side portion 31d positioned on the bottom wall 16 side of the casing 11 are formed on the periphery of the substrate 31.

On the front surface side portion 31a, an interface unit 32 is provided. The interface unit 32 is provided with total of twelve photoelectric converters 32a, and these photoelectric converters 32a are provided along the extending direction of the front surface side portion 31a so as to be next to each other at a predetermined interval. That is, the line card 30 of the present embodiment is an Ethernet-use line card with 12 ports. Here, an optical fiber cable (not shown) is connected to the photoelectric converter 32a. Moreover, the photoelectric converter 32a converts an optical signal from the optical fiber cable into an electric signal so that this electric signal is transmitted to a first communication-use LSI 34, a second communication-use LSI 35 and a third communication-use LSI 36, which will be described later.

On the back surface side portion 31b, a connector 33 to be connected to the slot of the main board 23 (see FIG. 3) is provided. This connector 33 is provided with a connector main body 33a that is extended in the extending direction of the back surface side portion 31b and formed into a substantially rectangular parallelepiped shape and with a connector connecting portion 33b protruding from this connector main body 33a toward the main board 23 side (right side in the drawing). Moreover, by inserting the line card 30 into the casing 11 so as to follow the guide rail, the connector connecting portion 33b is inserted into the slot of the main board 23.

On a substantially center portion of the substrate 31, the first communication-use LSI 34 serving as a heat generating element is mounted. Moreover, the second communication-use LSI 35 serving as one of heat generating elements is mounted on a portion of the substrate 31 which is closer to the bottom wall side portion 31d than the first communication-use LSI 34 and which is adjacent to the connector main body 33a. Moreover, the third communication-use LSI 36 serving as the other heat generating element is mounted on a portion of the substrate 31 which is closer to the top wall side portion 31c than the first communication-use LSI 34 and which is spaced apart from the connector main body 33a further than from the second communication-use LSI 35. That is, the second communication-use LSI 35 and the third communication-use LSI 36 are provided so as to be next to each other in the extending direction of the cooling air flow passage FC shown in FIG. 3, and are arranged so as to shift in a direction intersecting with the cool air flow passage FC.

Here, all the communication-use LSIs 34, 35 and 36 process a high speed signal, and therefore, their temperatures become very high during the operation. However, the temperature of the first communication-use LSI 34 does not become high so much in comparison with those of the second and third communication-use LSIs 35 and 36. Therefore, to each of the second and third communication-use LSIs 35 and 36, a heat sink having a comparatively large size and large surface area is attached. On the other hand, to the first communication-use LSI 34, a heat sink having a size smaller than those of the heat sinks attached to the second and third communication-use LSIs 35 and 36 is attached.

The heat generating elements required to be more exactly cooled among the plurality of heat generating elements mounted on the substrate 31 are the communication-use LSIs 34, 35 and 36 that are provided adjacent to each other. The followings are explanation of detailed configurations of the heat sinks for cooling these heat generating elements, that is, the communication-use LSIs 34, 35 and 36, and explanation of how to flow the cooling air W to these heat sinks in detail. Note that other heat generating elements 37 and 38 such as a controller (CPU) which controls the DC/DC converter and the line card 30 are also mounted on the substrate 31. To each of the other heat generating elements 37 and 38, a heat sink having a smaller size is attached because of a smaller amount of heat generation.

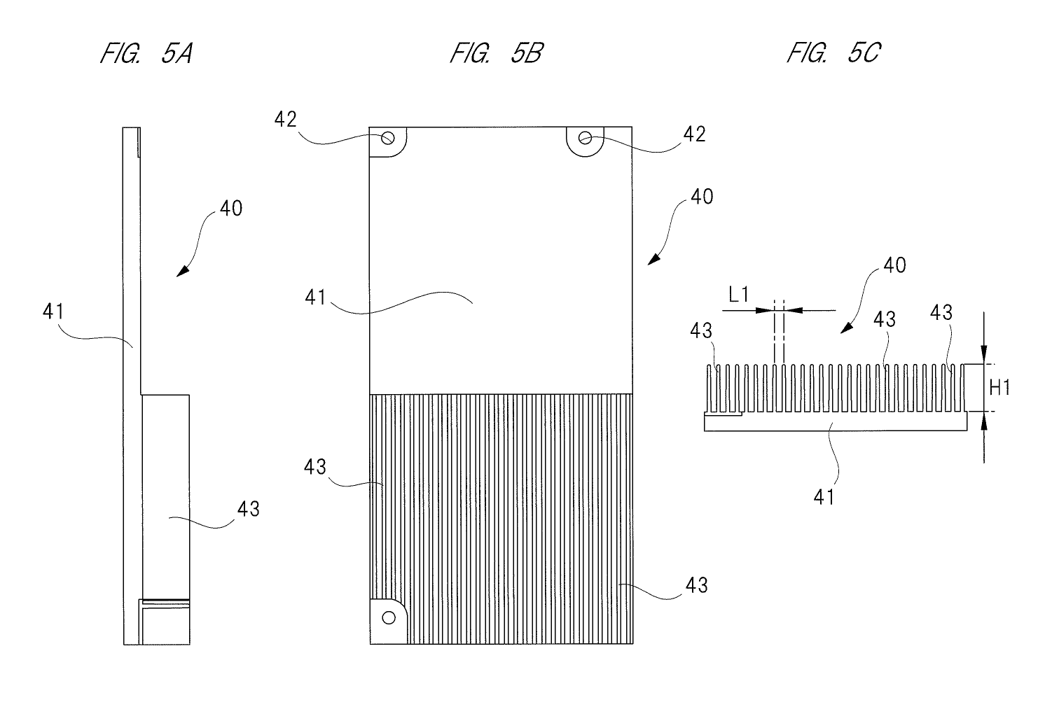

FIGS. 5A, 5B and 5C show details of the first heat sink used for cooling the first communication-use LSI.

As shown in FIGS. 5A, 5B and 5C, the first heat sink 40 used for cooling the first communication-use LSI 34 (see FIG. 4) is formed into a substantially rectangular shape by a cast molding process and a cutting process for an aluminum material having a superior heat conductivity or others. The first heat sink 40 is provided with a base portion 41 formed into a flat plate shape, and screw holes 42 through which fixing screws (not shown) for fixing the first heat sink 40 onto the substrate 31 are inserted are provided on three corners of the four corners of the base portion 41.

In a state in which the first heat sink 40 is fixed onto the substrate 31 (see FIG. 4), a plurality of fins 43 are integrally formed on the base portion 41 on the bottom wall side portion 31d side. These fins 43 are formed so as to protrude from the base portion 41 in a vertical direction as shown in FIGS. 5A and 5C, and besides, are linearly extended from the bottom wall side portion 31d of the substrate 31 toward the top wall side portion 31c as shown in FIG. 4 and FIG. 5B. In other words, the extending direction of the fins 43 is coincident with the extending direction of the cooling air flow passage FC (see FIG. 3). Thus, the cooling air W is easily introduced to an interval between the fins 43. Note that the height dimension H1 of the fine 43 is set to about 15 mm, and the interval dimension L1 between the fins 43 is set to about 4 mm.

As shown in FIG. 4, the first communication-use LSI 34 is arranged between the base portion 41 on the formation side of the fins 43 and the substrate 31. An elastically-deformable heat transfer sheet (not shown) is interposed between the first communication-use LSI 34 and the base portion 41, so that the entire surface of the first communication-use LSI 34 is made in contact with the first heat sink 40 through the heat transfer sheet.

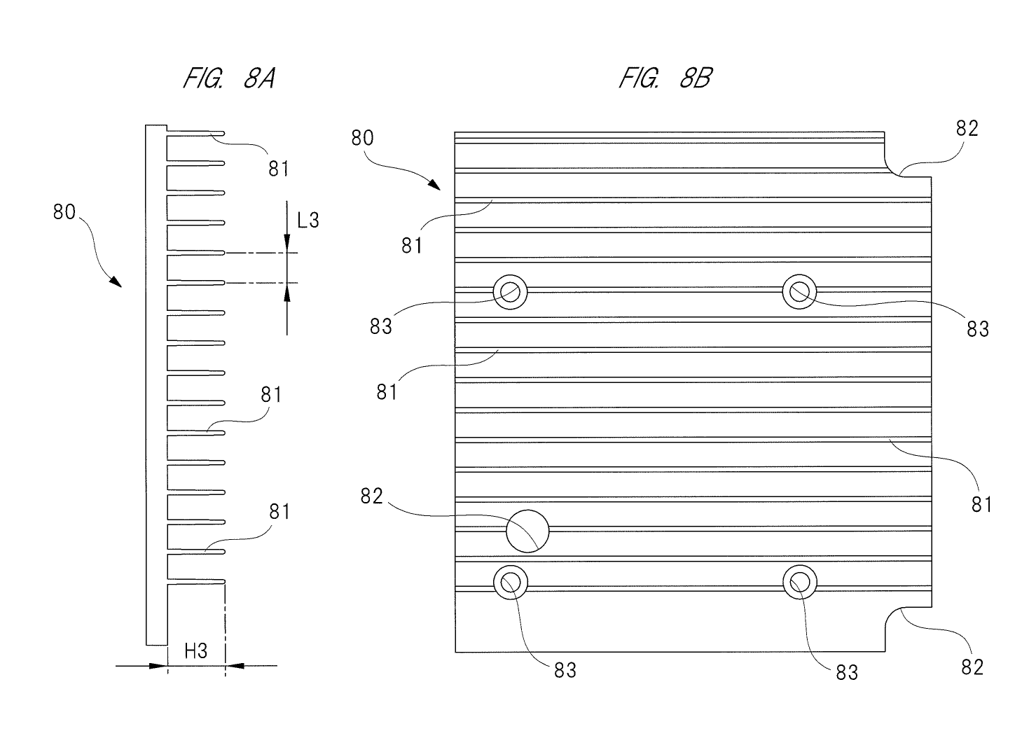

On the other hand, no fins 43 are provided on the base portion 41 on the top wall side portion 31c side. Thus, in a state in which the first heat sink 40 is fixed onto the substrate 31, the cooling air W is easily introduced between fins 81 (see FIG. 8) of a third heat sink 80 provided so as to correspond to the third communication-use LSI 36.

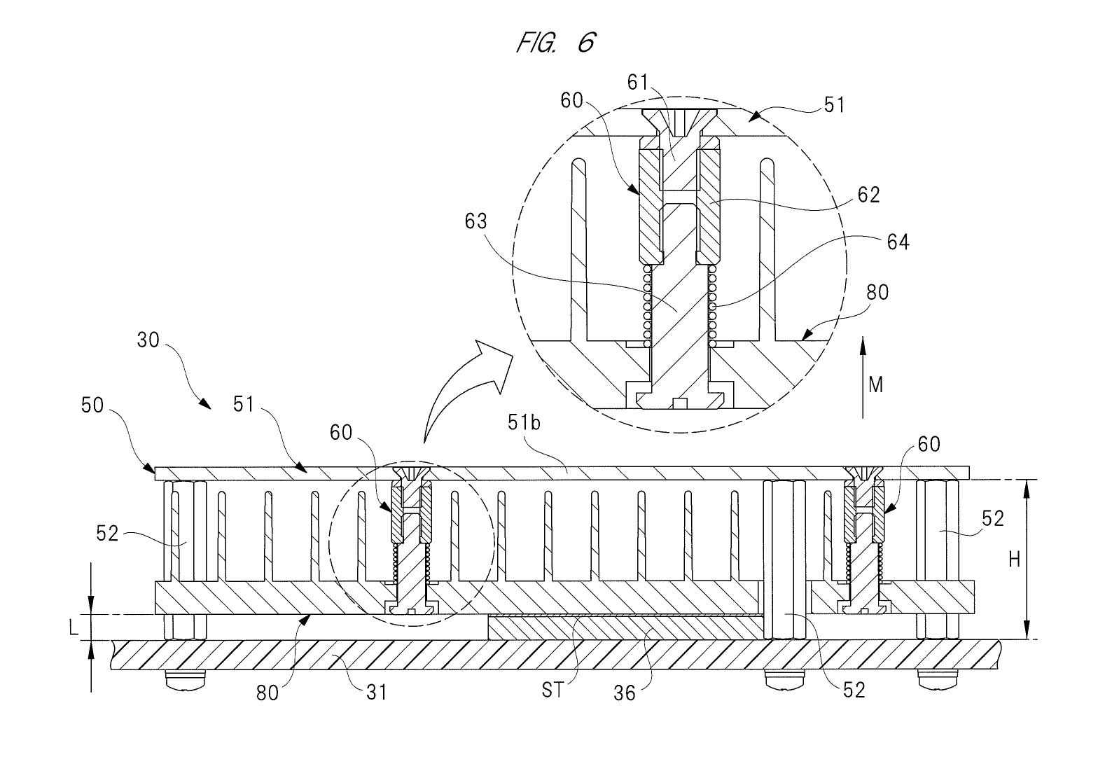

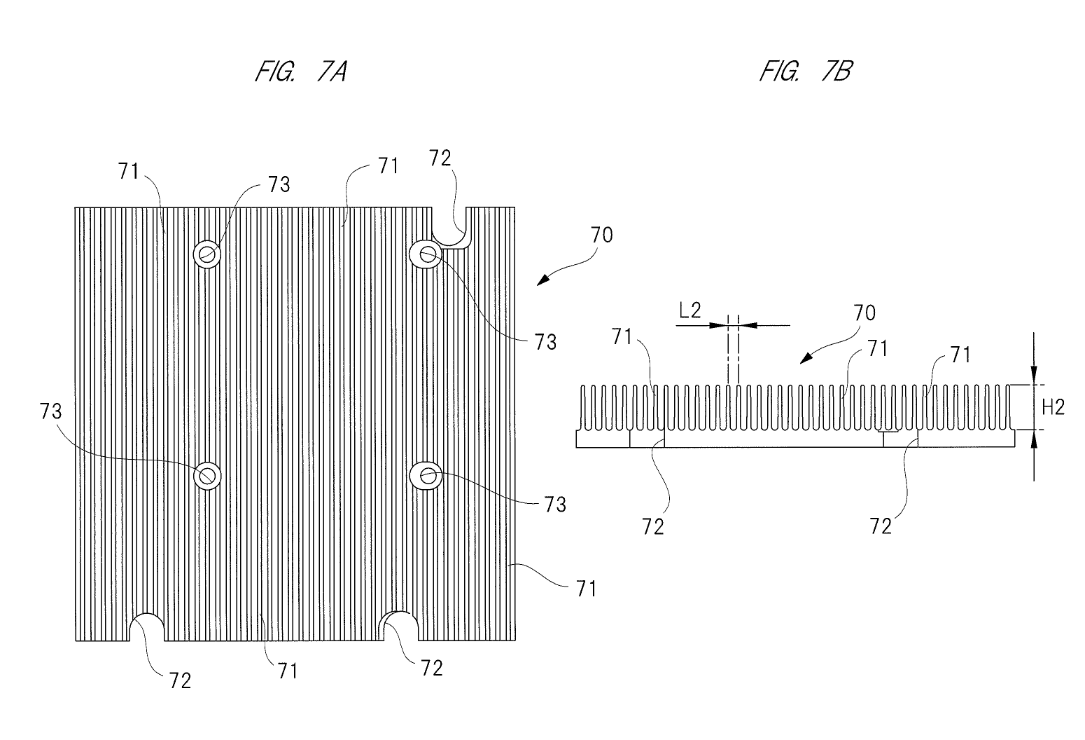

FIG. 6 is a cross-sectional view taken along a line B-B of FIG. 4, FIGS. 7A and 7B are views showing a second heat sink used for cooling the second communication-use LSI in detail, and FIGS. 8A and 8B are views showing a third heat sink used for cooling the third communication-use LSI in detail.

The second communication-use LSI 35 and the third communication-use LSI 36 are provided on the substrate 31 so as to be adjacent to each other. Therefore, in order to also improve the assembly performance of the line card 30, one heat sink unit 50 is attached to the second and third communication-use LSIs 35 and 36 in the present embodiment.

As shown in FIGS. 4 and 6, the heat sink unit 50 is provided with a fixing plate 51. The fixing plate 51 is formed into a substantially rectangular shape which is made of an aluminum plate having a superior thermal conductivity, and is fixed onto the substrate 31 through a plurality of fixing nuts 52 each having a length dimension of H. Thus, the fixing plate 51 is fixed at a position having a height dimension H from the front surface of the substrate 31.

In a state in which the fixing plate 51 is fixed onto the substrate 31 (see FIG. 4), a second heat sink fixing unit 51a is provided on the fixing plate 51 on the bottom wall side portion 31d side so as to correspond to the second communication-use LSI 35. On the other hand, a third heat sink fixing unit 51b is provided on the fixing plate 51 on the top wall side portion 31c side so as to correspond to the third communication-use LSI 36. In other words, the second heat sink fixing unit 51a and the third heat sink fixing unit 51b are also provided so as to be next to each other in the extending direction of the cooling air flow passage FC shown in FIG. 3, and are arranged so as to shift in a direction intersecting with the cooling air flow passage FC.

To the second heat sink fixing unit 51a, a second heat sink 70 used for removing the heat of the second communication-use LSI 35 is attached through a plurality of damper mechanisms 60. On the other hand, to the third heat sink fixing unit 51b, a third heat sink 80 used for removing the heat of the third communication-use LSI 36 is attached through a plurality of damper mechanisms 60.

Here, each of the damper mechanisms 60 is configured by a nut member 62 fixed onto the fixing plate 51 with a fixing screw 61, a supporting screw 63 that is fixed onto this nut member 62 and supports the second and third heat sinks 70 and 80 so as to be freely slide thereon, and a coil spring 64 that is attached between the nut member 62 and each of the second and third heat sinks 70, 80 in a compressed state.

Moreover, these damper mechanisms 60 support the second and third heat sinks 70 and 80 so that they are movable in an arrow M direction in the drawing. This manner absorbs an error of a dimension L obtained by adding the thickness dimension of the heat transfer sheet ST to a thickness dimension of each of the second and third communication-use LSIs 35 and 36. Therefore, by mounting the heat sink unit 50 on each of the second and third communication-use LSIs 35 and 36 through the heat transfer sheet, the pressing force of the coil spring 64 is applied thereto so that the entire surfaces of the second and third communication-use LSIs 35 and 36 are made in contact with the second and third heat sinks 70 and 80 through the heat transfer sheet ST, respectively.

As shown in FIG. 7, the second heat sink 70 serving as one of the heat sinks is attached to the second heat sink fixing unit 51a, and is arranged on the upstream side of the cooling air flow passage FC so as to correspond to the second communication-use LSI 35. To the second heat sink 70, a plurality of fins 71 are integrally provided. In a state in which the heat sink unit 50 is fixed onto the substrate 31 (see FIG. 4), these fins 71 are linearly extended from the bottom wall 16 of the casing 11 toward the top wall 15 along the extending direction on the upstream side of the cooling air flow passage FC (see FIG. 3). That is, the flowing direction of the cooling air W on the upstream side is the extending direction of the fins 71, so that the cooling air W is easily introduced between the fins 71. Here, the height dimension H2 of each fin 71 is set to about 13 mm, and the interval dimension L2 between the fins 71 is set to about 5 mm.

On the periphery of the second heat sink 70, a total of three nut avoiding portions 72 are provided in order to avoid the fixing nuts 52 (see FIG. 6). Inside these nut avoiding portions 72, the fixing nuts 52 are arranged so as to interpose a predetermined interval therebetween. Thus, the second heat sink 70 can smoothly move in the arrow M direction in FIG. 6.

Moreover, on portions (upper side in the drawing) close to the top wall 15 of the second heat sink 70, four damper attaching holes 73 are formed. To each of these damper attaching holes 73, a support screw 63 (see FIG. 6) of the damper mechanism 60 is attached so as to be freely slide therein. Line segments (not shown) connecting the damper attaching holes 73 to each other form a substantially square shape, so that the spring force of the coil spring 64 is evenly applied to the entire surface of the second communication-use LSI 35 formed into a substantially square shape. Therefore, the heat transfer sheet ST (see FIG. 6) can be exactly adhered onto both of the second communication-use LSI 35 and the second heat sink 70.

As shown in FIG. 8, the third heat sink 80 serving as the other heat sink is attached to the third heat sink fixing unit 51b, and is arranged on the downstream side of the cooling air flow passage FC so as to correspond to the third communication-use LSI 36. To the third heat sink 80, a plurality of fins 81 are integrally attached. In a state in which the heat sink unit 50 is fixed onto the substrate 31 (see FIG. 4), these fins 81 are linearly extended from the front wall 12 of the casing 11 toward the back wall 13 (exhaust outlet 20) along the extending direction of the cooling air flow passage FC on the downstream side (see FIG. 3). That is, the flowing direction of the cooling air W on the downstream side is the extending direction of the fins 81, so that the cooling air W is easily introduced between the fins 81. Here, the height dimension H3 of each fin 81 is set to about 14 mm, and the interval dimension L3 between the fins 81 is set to about 10 mm. That is, the interval between the fins 71 of the second heat sink 70 is made narrower than the interval between the fins 81 of the third heat sink 80 (L2<L3).

On portions of the third heat sink 80 on the connector 33 side (right side in the drawing) and on the first heat sink 40 side (left side in the drawing), a total of three nut avoiding portions 82 are formed in order to avoid the fixing nuts 52 (see FIG. 6). Inside these nut avoiding portions 82, the fixing nuts 52 are arranged so as to interpose a predetermined interval therebetween. Thus, the third heat sink 80 can be smoothly moved in the arrow M direction in FIG. 6.

Moreover, on portions (lower side in the drawing) close to the bottom wall 16 of the third heat sink 80, four damper attaching holes 83 are formed. To each of these damper attaching holes 83, a support screw 63 (see FIG. 6) of the damper mechanism 60 is attached so as to be freely slide therein. Line segments (not shown) connecting the damper attaching holes 83 to each other form a substantially square shape, so that the spring force of the coil spring 64 is evenly applied to the entire surface of the third communication-use LSI 36 formed into a substantially square shape. Therefore, the heat transfer sheet ST (see FIG. 6) can be exactly adhered onto both of the third communication-use LSI 36 and the third heat sink 80.

In this manner, by providing the second heat sink 70 so as to correspond to the second communication-use LSI 35, and besides, providing the third heat sink 80 so as to correspond to the third communication-use LSI 36, the second heat sink 70 and the third heat sink 80 are also provided so as to be next to each other in the extending direction of the cooling air flow passage FC shown in FIG. 3, and are arranged so as to be shifted in a direction intersecting with the cooling air flow passage FC.

Moreover, the extending direction of the fins 71 of the second heat sink 70 and the extending direction of the fins 81 of the third heat sink 80 intersect with each other (intersect with each other with 90 degrees in the present embodiment) so as to follow the extending direction of the cooling air flow passage FC shown in FIG. 3. Moreover, as shown in FIG. 4, between the second heat sink 70 and the third heat sink 80, an air-flow-through passage OS having a width dimension larger than the interval dimension L2 between the fins 71 and the interval dimension L3 between the fins 81 is formed.

Furthermore, as shown in FIG. 4, on a portion of the substrate 31 which is close to the bottom wall side portion 31d on the front surface side portion 31a side, a cooling-air introduction member made of a plastic plate is provided. This cooling-air introduction member 90 is used for introducing most of outside air (cooling air W) introduced from the air suction inlet 18 toward a rearward side portion (close to the back surface side portion 31d) of the substrate 31 on which the first heat sink 40, the second heat sink 70 and the third heat sink 80 are mounted, the portion being also on the lower side (close to the bottom wall side portion 31d) thereof.

In this manner, a low-temperature cooling air W can be easily introduced to each of the interval between the fins 71 and the interval between the fins 81, and besides, the high-temperature cooling air W that has passed through the portions between the fins 71 and between the fins 81 can be easily introduced toward the exhaust outlet 20.

Next, by using the drawings, the explanation is made about the flowing of the cooling air W inside the casing 11 in detail.

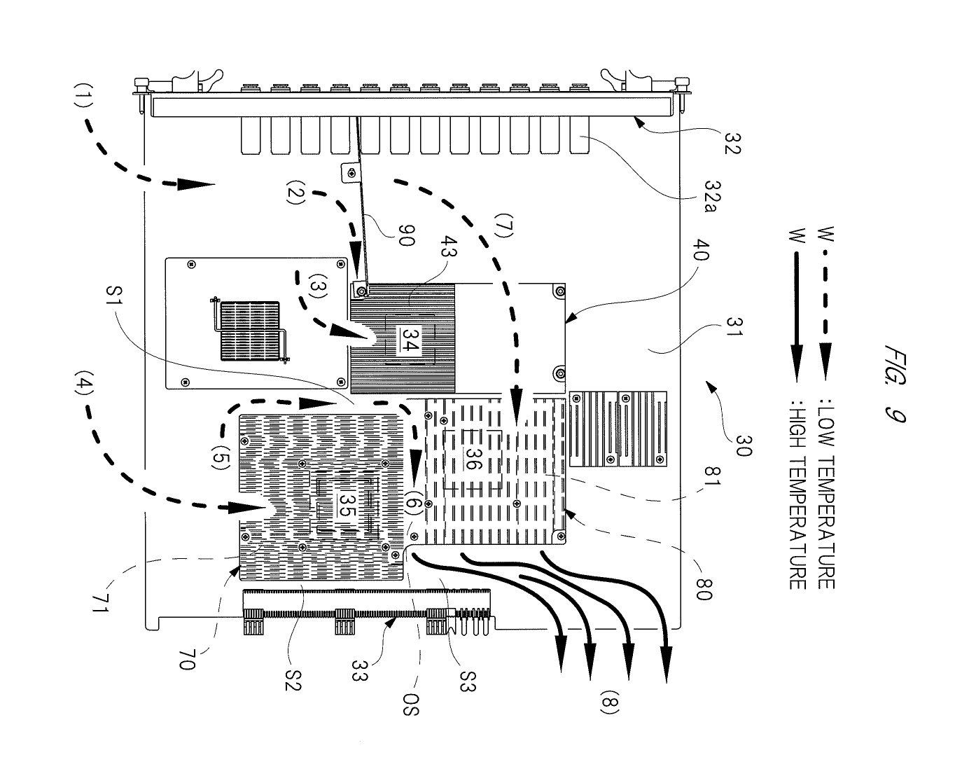

FIG. 9 is a view for explaining the flowing of the cooling air with respect to the substrate.

When the large-size fans 21 are rotationally driven, a low-temperature cooling air W (indicated by a broken-line arrow in the drawing) is introduced from the air suction inlet 18 into the casing 11 as shown in FIG. 9. The cooling air W that has introduced into the casing 11 is partially flowed toward the cooling-air introduction member 90 as shown by a broken-line arrow (1). Then, the cooling air W that has hit onto the cooling-air introduction member 90 flows along the cooling-air introduction member 90 as shown by a broken-line arrow (2). Then, as shown by a broken-line arrow (3), the cooling air flows into a portion between the fins 43 of the first heat sink 40, so that the first communication-use LSI 34 is cooled.

Moreover, the cooling air W introduced into the casing 11 partially flows into a portion between the fins 71 of the heat sink as shown by a broken-line arrow (4). Thus, the second communication-use LSI 35 is cooled. At this time, since the interval dimension L2 (see FIG. 7) between the fins 71 is narrow, the fins 71 function as a throttle relative to the flowing speed of the cooling air W. Therefore, the cooling air W that has not been allowed to flow between the fins 71 is flowed into a first space S1 between the first heat sink 40 and the second heat sink 70 as indicated by a broken line arrow (5).

Here, the first space S1 is set to be wider than a second space S2 between the second heat sink 70 and the connector 33, so that the cooling air W flows as indicated by the broken line arrow (5). Note that the first space S1 is formed by arranging the second heat sink 70 and the third heat sink 80 so as to shift in a direction intersecting with the cool air flow passage FC (see FIG. 3).

Then, the cooling air W that has flowed into the first space S1 passes through the air-flow-through passage OS between the second heat sink 70 and the third heat sink 80 as indicated by a broken line arrow (6). In this manner, a high-temperature cooling air W that has come out between the fins 71 is promptly introduced toward the exhaust outlet 20. Moreover, by allowing a low-temperature cooling air W to pass through the air-flow-through passage OS, the high-temperature cooling air W that has come out between the fins 71 is prevented from being directly made into contact with the third heat sink 80. Thus, decrease in the cooling efficiency of the third heat sink 80 is prevented.

Thus, the cooling air W that has passed through the air-flow-through passage OS becomes the high-temperature cooling air W, and is directed toward the exhaust outlet 20 as indicated by a solid line arrow (8) through the third space S3 between the third heat sink 80 and the connector 33. Note that the third space S3 is set to be wider than the first space S1 and the second space S2, and the third space S3 is formed by arranging the second heat sink 70 and the third heat sink 80 so as to shift in a direction intersecting with the cooling air flow passage FC (see FIG. 3).

Moreover, the cooling air W introduced into the casing 11 partially gets over the cooling-air introduction member 90 and flows into a portion between the fins 81 of the third heat sink 80 as indicated by a broken line arrow (7). Thus, the third communication-use LSI 36 is cooled. At this time, since the fins 43 of the first heat sink 40 do not become a barrier, the cooling air W can be smoothly flowed into the portion between the fins 81. Here, although the cooling air W that has come from the portion between the fins 43 of the first heat sink 40 partially flows into the portion between the fins 81, the amount of heat generation of the first communication-use LSI 34 is extremely smaller than those of the second and third communication-use LSIs 35 and 36. Therefore, the cooling efficiency of the third communication-use LSI 36 is not lowered.

Most of the high-temperature cooling air W that has come out between the fins 81 of the third heat sink 80 is directly directed toward the exhaust outlet 20 as indicated by a solid-line arrow (8). However, the high-temperature cooling air W that has come out between the fins 81 of the third heat sink 80 is partially directed toward the exhaust outlet 20 through the third space S3 as indicated by the solid-line arrow (8).

As described above in detail, in the line card 30 according to the present embodiment, the extending direction of the fins 71 of the second heat sink 70 so as to correspond to the second communication-use LSI 35 and the extending direction of the fins 81 of the third heat sink 80 so as to correspond to the third communication-use LSI 36 are made to intersect with each other, and therefore, the cooling air W that has passed through the second heat sink 70 can be prevented from passing through the third heat sink 80.

Thus, it becomes possible to supply a cooling air W that is not warmed can be supplied to both of the second heat sink 70 and the third heat sink 80. Therefore, the heat radiating property of each of the second and third communication-use LSIs 35 and 36 provided so as to be adjacent to each other is improved. As a result, both of the second and third communication-use LSIs 35 and 36 can be more efficiently cooled.

Moreover, in the line card 30 according to the present embodiment, the flowing direction of the cooling air W on the upstream side of the cooling air flow passage FC formed on the substrate 31 is the extending direction of the fins 71 of the second heat sink 70, and the flowing direction of the cooling air W on the downstream side of the cooling air flow passage FC is the extending direction of the fins 81 of the third heat sink 80, and therefore, the cooling air W can be easily introduced to the portions between the fins 71 and between the fins 81.

Furthermore, in the line card 30 according to the present embodiment, the second heat sink 70 is formed on the upstream side of the cooling air flow passage FC formed on the substrate 31, and the third heat sink 80 is formed on the downstream side of the cooling air flow passage FC, and the interval (interval dimension L2) between the fins 71 of the second heat sink 70 is made narrower than the interval (interval dimension L3) between the fins 81 of the third heat sink 80 (L2<L3).

Thus, the fins 71 of the second heat sink 70 can function as a throttle, and the low-temperature air W on the upstream side of the cooling air flow passage FC can be partially supplied to the third heat sink 80 on the downstream side of the cooling air flow passage FC. Therefore, both of the second and third communication-use LSIs 35 and 36 can be more efficiently cooled.

Moreover, in the line card 30 according to the present embodiment, the cooling-air introduction member 90 for introducing the cooling air W to the first and second heat sinks 40 and 70 is formed on the substrate 31, and therefore, the first communication-use LSI 34 and the second communication-use LSI 35 can be more efficiently cooled.

Furthermore, in the line card 30 according to the present embodiment, the second heat sink 70 and the third heat sink 80 are formed so as to be next to each other in the extending direction of the cooling air flow passage FC formed on the substrate 31 and are arranged so as to shift in a direction intersecting with the cooling air flow passage FC.

In this manner, a low-temperature air W is supplied to the air-flow-through passage OS between the second and third heat sinks 70 and 80. As a result, the lowering of the cooling efficiency of the third heat sink 80 can be prevented. Moreover, the high-temperature cooling air W that has come out between the fins 71 can be promptly introduced toward the exhaust outlet 20, so that the high-temperature cooling air W can be prevented from staying inside the casing 11 (on the substrate 31).

It is needless to say that the present invention is not limited to the foregoing embodiments and various modifications and alterations can be made within the scope of the present invention. In the above-described embodiment, the case in which the interval dimension L2 between the fins 71 of the second heat sink 70 is smaller than the interval dimension L3 between the fins 81 of the third heat sink 80 has been described. However, the present invention is not limited to this case. For example, the interval dimension L2 and the interval dimension L3 may be set to the same value (L2=L3) as long as the amount of heat generation of the second communication-use LSI 35 is larger than the amount of heat generation of the third communication-use LSI 36, or the interval dimension L2 may be set to be larger than the interval dimension L3 (L2>L3).

Moreover, in the above-described embodiment, the device in which the large-size fans 21 for carrying the cooling air W inside the casing 11 are provided on the downstream side of the cooling air flow passage FC, that is, on the exhaust outlet 20 is described. However, the present invention is not limited to this, and the large-size fans 21 can be provided on the upstream side of the cooling air flow passage FC, that is, on the air suction inlet 18. Furthermore, in order to further increase the cooling efficiency, the large-size fans 21 can be provided on both of the air suction inlet 18 and the exhaust outlet 20.

What is claimed is:

1. A signal transmission device comprising:
heat generating elements mounted on a substrate; and
heat sinks used for cooling the heat generating elements,
wherein an extending direction of fins of one of the heat sinks corresponding to one of the heat generating elements formed on the substrate so as to be adjacent to each other intersects with an extending direction of fins of the other of the heat sinks corresponding to the other of the heat generating elements.

2. The signal transmission device according to claim 1,
wherein a flowing direction of a cooling air on an upstream side of a cooling air flow passage formed on the substrate is an extending direction of the fins of one of the heat sinks, and
a flowing direction of the cooling air on a downstream side of the cooling air flow passage is an extending direction of the fins of the other of the heat sinks.

3. The signal transmission device according to claim 1,
wherein one of the heat sinks is provided on the upstream side of the cooling air flow passage formed on the substrate while the other of the heat sinks is provided on the downstream side of the cooling air flow passage, and
an interval between the fins of one of the heat sinks is made narrower than an interval between the fins of the other of the heat sinks.

4. The signal transmission device according to claim 1,
wherein a cooling-air introduction member used for introducing a cooling air into the heat sink is provided on the substrate.

5. The signal transmission device according to claim 1,
wherein the one of the heat sinks and the other of the heat sinks are provided so as to be next to each other in an extending direction of the cooling air flow passage formed on the substrate, and is arranged so as to shift in a direction intersecting with the cooling air flow passage.

6. A cooling device comprising:
a signal transmission device;
a casing used for housing the signal transmission device; and
a cooling mechanism that introduces outside air into the casing and exhausts heat from the signal transmission device out of the casing,
wherein the signal transmission device includes:
heat generating elements mounted on a substrate; and
heat sinks used for cooling the heat generating elements,
an extending direction of fins of one of the heat sinks corresponding to one of the heat generating elements provided on the substrate so as to be adjacent to each other intersects with an extending direction of fins of the other of the heat sinks corresponding to the other of the heat generating elements, and
the cooling mechanism includes:
an air suction inlet and an exhaust outlet provided on the casing; and
fans provided on at least either one of the air suction inlet and the exhaust outlet so as to form a cooling air flow passage on the substrate.

7. The cooling device according to claim 6,
wherein a flowing direction of a cooling air on an upstream side of the cooling air flow passage is an extending direction of the fins of one of the heat sinks, and
a flowing direction of the cooling air on a downstream side of the cooling air flow passage is an extending direction of the fins of the other of the heat sinks.

8. The cooling device according to claim 6,
wherein one of the heat sinks is provided on the upstream side of the cooling air flow passage while the other of the heat sinks is provided on the downstream side of the cooling air flow passage, and
an interval between the fins of one of the heat sinks is made narrower than an interval between the fins of the other of the heat sinks.

9. The cooling device according to claim 6,
wherein a cooling-air introduction member used for introducing a cooling air into the heat sink is provided on the substrate.

10. The cooling device according to claim 6,
wherein the one of the heat sinks and the other of the heat sinks are provided so as to be next to each other in an extending direction of the cooling air flow passage, and is arranged so as to shift in a direction intersecting with the cooling air flow passage.
